(19) United States
(12) Patent Application Publication
(10) Pub. No.: US 2011/0111186 A1
(43) Pub. Date: May 12, 2011

(54) INORGANIC LAYER, DISPLAY DEVICE INCLUDING THE INORGANIC LAYER AND METHOD FOR MANUFACTURING THE DISPLAY DEVICE

(75) Inventors: Kie Hyun Nam, Yongin-City (KR); Hyun-Woo Koo, Yongin-City (KR); Sang-Joon Seo, Yongin-City (KR); Jung-Woo Moon, Yongin-City (KR); Hyung-Sik Kim, Yongin-City (KR)

(73) Assignee: Samsung Mobile Display Co., Ltd., Yongin-City (KR)

(21) Appl. No.: 12/786,225

(22) Filed: May 24, 2010

(30) Foreign Application Priority Data
Nov. 10, 2009 (KR) 10-2009-0108271

(51) Int. Cl. B32B 3/10; B32B 9/04; B32B 7/02; B32B 17/06; B05D 3/06; C23C 14/34

(52) U.S. Cl. 428/195.1; 428/688; 428/218; 428/698; 428/702; 428/446; 428/426; 427/554; 204/192.12

(57) ABSTRACT

Disclosed are an inorganic layer which is formed on one side or both sides of a substrate and has at least a portion irradiated with a laser, a display device including the inorganic layer, and a manufacturing method thereof.

### CROSS-REFERENCE TO RELATED APPLICATIONS

This application claims priority to and the benefit of Korean Patent Application No. 10-2009-0108271 filed in the Korean Intellectual Property Office on Nov. 10, 2009, the entire contents of which are incorporated herein by reference.

### BACKGROUND OF THE INVENTION

1. Field of the Invention

This disclosure relates to an inorganic layer, a display device including the inorganic layer, and a method for manufacturing the same.

2. Description of the Related Art

A display device such as an organic light emitting diode (OLED) display device includes a substrate with a device formed thereon.

As for the substrate, glass substrate, silicon wafer, or a polymer film may be used, and at least one inorganic layer may be deposited on the substrate. The inorganic layer may be a substrate protective layer added in order to complement the moisture permeability and gas permeability of the material of the substrate, an interlayer dielectric layer disposed between a plurality of conductive layers or between a plurality of semiconductor layers, or a patterned insulation pattern.

### SUMMARY OF THE INVENTION

An aspect of the present embodiments provides an inorganic layer, a display device including the inorganic layer, and a method for manufacturing the display device.

Another aspect of the present embodiments provides an inorganic layer that protects a substrate or prevents a device formed on the substrate from being deteriorated.

Yet another aspect of the present embodiments provides a display device including the inorganic layer.

Still another aspect of the present embodiments provides a method for manufacturing the display device.

According to an embodiment, an inorganic layer may be formed on one side or both sides of a substrate and at least a portion of the inorganic layer is irradiated with a laser.

According to another embodiment, a display device includes a substrate, an inorganic layer disposed on one side or both sides of the substrate, a portion of which has been irradiated with a laser, and a device formed on the inorganic layer.

According to another embodiment, a method for manufacturing a display device includes providing an inorganic layer on a substrate, irradiating the inorganic layer with a laser, and providing a device on the inorganic layer irradiated with the laser.

A portion irradiated with the laser may have a layer density at least about 5% higher than a portion not irradiated with the laser.

A portion irradiated with the laser may have a hydrogen content of from about 1% to about 90%, compared with a portion not irradiated with the laser.

The inorganic layer may include an inorganic layer capable of absorbing laser.

The inorganic material may include an oxide, a nitride or an oxi-nitride of silicon (Si), titanium (Ti), tantalum (Ta), barium (Ba), zinc (Zn), aluminum (Al), or a combination thereof.

The inorganic layer may be a substrate protective layer, an interlayer insulating layer, an insulation pattern or a combination thereof.

The substrate may be at least one of a glass substrate, a polymer film and a silicon wafer.

The device may be a semiconductor, an electrode, a thin film transistor, an organic light emitting element, or a combination thereof.

The laser used in the irradiation of the laser may be an excimer laser, a Nd:YAG continuous wave-type laser, a Nd:YAG pulse-type laser or a carbon dioxide (CO₂) laser.

The inorganic layer may be formed, for example, through a chemical vapor deposition (CVD) process, a sputtering process or a wet coating process.

### BRIEF DESCRIPTION OF THE DRAWINGS

FIG. 1 is a cross-sectional view illustrating a substrate protective layer in accordance with one embodiment.

FIG. 2 is a cross-sectional view illustrating a display device in accordance with one embodiment.

FIGS. 3 and 4 are cross-sectional views sequentially describing a method for manufacturing the display device shown in FIG. 2.

### DETAILED DESCRIPTION OF THE INVENTION

This disclosure will be described more fully hereinafter with reference to the accompanying drawings, in which exemplary embodiments of this disclosure are shown. As those skilled in the art would realize, the described embodiments may be modified in various different ways, all without departing from the spirit or scope of this disclosure.

In the drawings, the thickness of layers, films, panels, regions, etc., are not necessarily drawn to scale. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

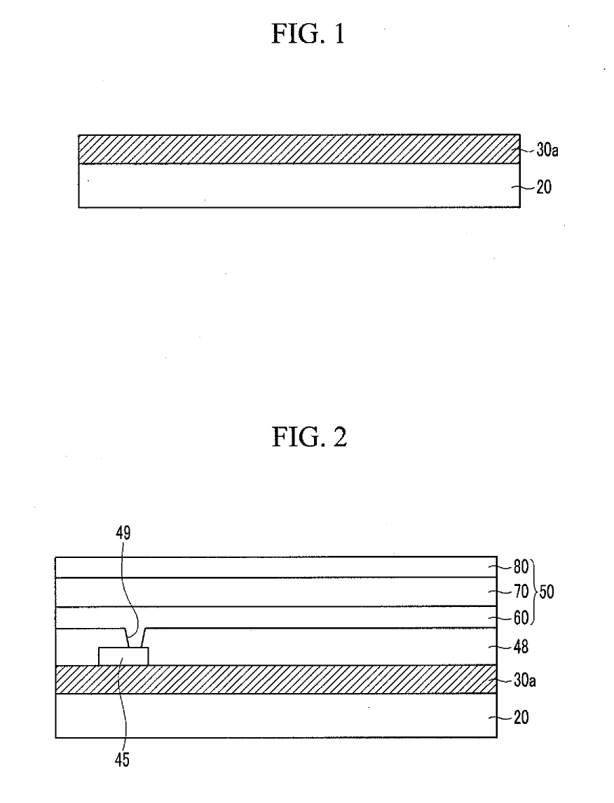

Referring to FIG. 1, illustrated is an inorganic layer according to one embodiment.

FIG. 1 exemplarily shows a case where the inorganic layer is used as a substrate protective layer.

FIG. 1 is a cross-sectional view illustrating a substrate protective layer in accordance with one embodiment.

Referring to FIG. 1, a substrate protective layer 30a is formed on one side of a substrate 20.

The substrate 20 may be, for example, a glass substrate, a polymer film, or a silicon wafer. The substrate 20 may be a polymer film made of, for example, polyimide, polyacrylate, polyethylene ether phthalate, polyethylene naphthalate, polycarbonate, polyarylate, polyetherimide, polyethersulfone, triacetic acid cellulose, polyvinylidene chloride, polyvinylidene fluoride, ethylene-vinyl alcohol copolymer, or a combination thereof.

The substrate protective layer 30a includes inorganic particles capable of absorbing a laser beam.

The inorganic particles capable of absorbing a laser beam may be an oxide, a nitride or an oxi-nitride of a semi-metal or metal, for example, an oxide, a nitride or an oxi-nitride of silicon (Si), titanium (Ti), tantalum (Ta), barium (Ba), zinc (Zn), aluminum (Al) or a combination thereof. The inorganic particles may have a size of from about 5 nm to about 50 μm.

The substrate protective layer 30a includes a portion irradiated with a laser, for example, a surface portion irradiated with a laser.

The portion irradiated with a laser has a density higher than a portion not irradiated with a laser. For example, when measured through an x-ray reflectivity (XRR) process, the portion irradiated with a laser may have a layer density about 5% higher than the portion not irradiated with a laser.

As described above, by including the portion irradiated with a laser in the substrate protective layer and thereby increasing the layer density, it is possible to effectively protect the substrate from being permeated with moisture and gas. Therefore, it is possible to protect the substrate from being deteriorated by moisture and gas originating from the exterior.

Also, a portion irradiated with a laser has a lower hydrogen content than a portion not irradiated with a laser. The portion irradiated with a laser may have a hydrogen content of from about 1% to about 90%, compared with the portion not irradiated with a laser. For example, the portion not irradiated with a laser may have a hydrogen content of from about 10% to about 30% when measured with FTIR, and a portion irradiated with a laser may have a hydrogen content of from about 0.5% to about 20%.

In the above, embodiment are described wherein the inorganic layer is used as a substrate protective layer. However, this disclosure is not so limited and may also be applied to an inorganic layer, for example, an interlayer dielectric layer including a gate insulating layer, or an insulation pattern such as an etching stopper.

When a thin film transistor is formed on a substrate, the inorganic layer may be used as a gate insulating layer or an etching stopper. As described above, the portion of the inorganic layer irradiated with a laser has a lower hydrogen content than the portion not irradiated with a laser. As the gate insulating layer or the etching stopper has a low hydrogen content, hydrogen diffuses into a semiconductor layer and thus it is possible to decrease the performance deterioration of a thin film transistor. The hydrogen diffusion prevention effect becomes greater when the thin film transistor includes an oxide semiconductor.

Hereafter, a display device including an inorganic layer will be described.

Herein, a case where the inorganic layer is used as a substrate protective layer will be exemplarily described, and among the display devices, an organic light emitting diode (OLED) display will be exemplarily described. However, this disclosure is not limited thereto.

FIG. 2 is a cross-sectional view illustrating a display device in accordance with one embodiment.

Referring to FIG. 2, the display device according to one embodiment includes a substrate 20, a substrate protective layer 30a formed on the substrate 20, and a device 40 formed on the substrate protective layer 30a.

The substrate 20 and the substrate protective layer 30a are as described above. The device 40 includes a thin film transistor (TFT) 45 and an organic light emitting diode (OLED) 50 connected to the thin film transistor 45. A planarization layer 48 may be formed between the thin film transistor 45 and the OLED 50, and the thin film transistor 45 and the OLED 50 may be electrically connected to each other through a contact hole 49 formed in the planarization layer 48.

The OLED 50 includes a first electrode 60, an organic light emitting element 70, and a second electrode 80.

Any one between the first electrode 60 and the second electrode 80 may be an anode and the other one may be a cathode. The anode is an electrode into which holes are injected, and it may be made of a transparent conductive material having a high work function and capable of emitting light, for example, ITO or IZO. The cathode is an electrode into which electrons are injected, and it may be formed of a conductive material having a low work function but having little or no affect on an organic material, for example, aluminum (Al), calcium (Ca) and barium (Ba).

The organic light emitting element 70 may include an organic emission layer and an auxiliary layer. The organic emission layer includes an organic material that may emit light when voltage is applied to the first electrode 60 and the second electrode 80, and the auxiliary layer may include at least one of a hole transporting layer (HTL), a hole injecting layer (HIL), an electron injecting layer (EIL), and an electron transporting layer (ETL), which are disposed between the first electrode 60 and an organic emission layer and/or between the second electrode 80 and the organic emission layer and achieve a balance between electrons and holes.

The device is not limited to the above-described organic light emitting diode (OLED) display, but it may be any one of diverse forms of devices that may be formed on a substrate, e.g., a semiconductor, an electrode, or a thin film transistor including a semiconductor and an electrode.

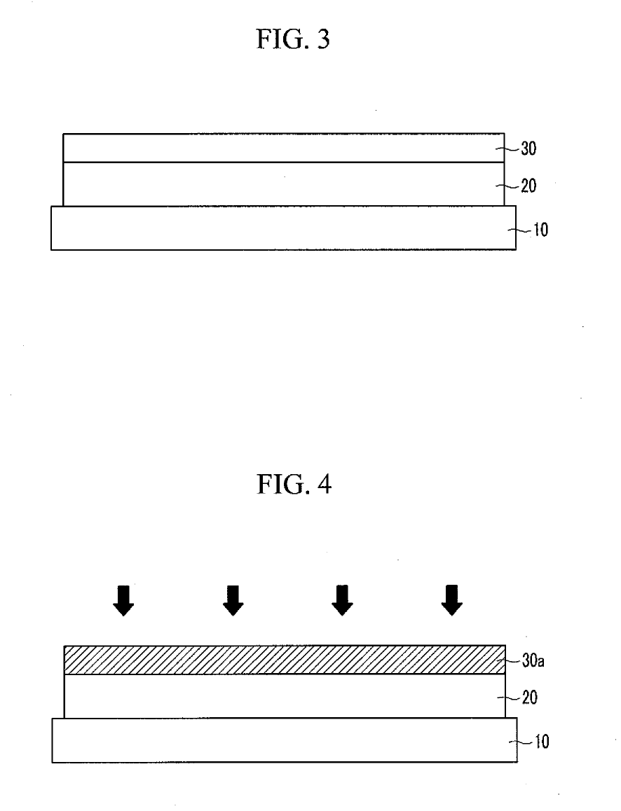

Hereafter, a method for manufacturing the above-described display device will be described with reference to FIGS. 3 and 4 with FIG. 2.

FIGS. 3 and 4 are cross-sectional views describing a method for manufacturing the display device shown in FIG. 2.

In this embodiment, embodiments in which a polymer film is used as the substrate 20 will be exemplarily described.

Referring to FIG. 3, the substrate 20 is prepared on a glass plate 10. The glass plate 10 may be used as a supporter for the substrate 20 during the manufacturing process. The substrate 20 may be formed by coating a polymer resin solution on the glass plate 10.

Subsequently, a substrate protective layer 30 is formed on the substrate 20. The substrate protective layer 30 may be an inorganic layer including inorganic particles capable of absorbing a laser beam. Non-limiting examples of the inorganic particles capable of absorbing a laser beam include an oxide, a nitride or an oxi-nitride of silicon (Si), titanium (Ti), tantalum (Ta), barium (Ba), zinc (Zn), aluminum (Al), or a combination thereof.

The substrate protective layer 30 may be formed, for example, through a chemical vapor deposition (CVD) process or a sputtering process. Also, the substrate protective layer 30 may be formed through a wet method, such as spin coating, a slit coating or a sol-gel method. When the substrate protective layer 30 is formed through a wet method, the inorganic particles are prepared in the form of a precursor that may be dissolved, mixed with a solvent, applied, and then treated with heat.

Referring to FIG. 4, the substrate protective layer 30 is irradiated with a laser to thereby form a laser-irradiated substrate protective layer 30a. Due to the laser irradiation, at least a portion of the substrate protective layer 30 is irradiated with a laser, and the laser-irradiated portion comes to have a high density. Thus the property of blocking moisture and oxygen is improved.

Referring to FIG. 2, an OLED display is manufactured by forming the thin film transistor 45, the planarization layer 48, the first electrode 60, the organic light emitting element 70 and the second electrode 80 on the substrate protective layer 30a.

The following examples illustrate this disclosure in more detail. These examples, however, are not in any sense to be interpreted as limiting the scope of this disclosure.

### Example 1

A silicon nitride layer having a thickness of about 2000 Å is deposited by putting a silicon wafer in a chamber and performing a plasma enhanced chemical vapor deposition (PECVD) process at a substrate temperature of about 200° C. for about 100 seconds, while using silane (SiH₄) gas as a source gas and supplying both ammonia (NH₃) gas and nitrogen (N₂) gas.

Hydrogen content included in the deposited silicon nitride layer is measured with a Fourier transform infrared spectroscopy (FTIR), and layer density is measured through an x-ray reflectivity (XRR) process.

Subsequently, the silicon nitride layer is irradiated with a Nd:YAG CW type solid laser having a wavelength of beam width of 810 nm at a uniform speed with an output of 300 W/cm².

Hydrogen content included in the laser-irradiated silicon nitride layer is measured with an FTIR, and layer density is measured through an XRR process.

### Example 2

A silicon nitride layer is formed according to the same method as Example 1, except that the silicon nitride layer is irradiated with a Nd:YAG solid laser having a wavelength of 810 nm with an output of 600 W/cm², and the hydrogen content and the layer density are measured.

### Example 3

An aluminum oxide layer having a thickness of about 2000 Å is deposited on a silicon wafer by performing a plasma enhanced chemical vapor deposition (PECVD) process at a substrate temperature of about 200° C. for about 100 seconds, while using trimethylaluminum as a source and supplying N₂O gas.

Subsequently, the aluminum oxide layer is irradiated with a Nd:YAG solid laser having a wavelength of 810 nm at a uniform speed with an output of 300 W/cm².

Hydrogen content included in the laser-irradiated aluminum oxide layer is measured with an FTIR, and layer density is measured through an XRR process.

### Evaluation

The measurement results of the hydrogen content and the layer density measured in Examples 1 to 3 are shown in the following Table 1.

TABLE 1

| | Layer density | | Hydrogen content | |
|---|---|---|---|---|
| | Before laser | After laser | Before laser | After laser |
| | irradiation | irradiation | irradiation | irradiation |
| Example 1 | 2.43 | 2.59 | 26 | 19 |
| Example 2 | 2.43 | 2.77 | 26 | 10 |
| Example 3 | 2.64 | 2.98 | 12 | 4.5 |

The hydrogen contents and layer densities before and after the laser irradiation are compared based on Table 1, and the layer density variation percentage and hydrogen content variation percentage after laser irradiation are calculated. The results are as shown in the following Table 2.

TABLE 2

| | Layer density variation | Hydrogen content |
|---|---|---|
| | percentage after laser | percentage remaining |
| | irradiation (%) | after laser irradiation (%) |
| Example 1 | 6.6 | 73 |
| Example 2 | 14.0 | 38 |
| Example 3 | 12.9 | 37.5 |

It may be seen from Tables 1 and 2, the layer densities of the inorganic layer are increased after the laser irradiation, while the hydrogen contents are decreased.

While this disclosure has been described in connection with what is presently considered to be practical exemplary embodiments, it is to be understood that the present embodiments are not limited to the disclosed embodiments, but, on the contrary, is intended to cover various modifications and equivalent arrangements included within the spirit and scope of the appended claims.

What is claimed is:

1. An inorganic layer disposed on one side or both sides of a substrate, wherein at least a portion of the inorganic layer has been irradiated with a laser.

2. The inorganic layer of claim 1, wherein the laser-irradiated portion has a layer density at least about 5% higher than a portion not irradiated with the laser.

3. The inorganic layer of claim 1, wherein the laser-irradiated portion has a hydrogen content of from about 1% to about 90%, compared with a portion not irradiated with the laser.

4. The inorganic layer of claim 1, wherein the inorganic layer includes an inorganic material capable of absorbing the laser.

5. The inorganic layer of claim 4, wherein the inorganic material includes an oxide, a nitride or an oxi-nitride of silicon (Si), titanium (Ti), tantalum (Ta), barium (Ba), zinc (Zn), aluminum (Al), or a combination thereof.

6. The inorganic layer of claim 1, wherein the inorganic layer is a substrate protective layer, an interlayer insulating layer, an insulation pattern, or a combination thereof.

7. A display device, comprising:
a substrate;
an inorganic layer formed on one side or both sides of the substrate and having at least a portion irradiated with a laser; and
a device formed on the inorganic layer.

8. The display device of claim 7, wherein the laser-irradiated portion of the inorganic layer has a layer density at least about 5% higher than a portion not irradiated with the laser.

9. The display device of claim 7, wherein the laser-irradiated portion has a hydrogen content of from about 1% to about 90%, compared with a portion not irradiated with the laser.

10. The display device of claim 7, wherein the inorganic layer includes an inorganic material capable of absorbing the laser.

11. The display device of claim 10, wherein the inorganic material includes an oxide, a nitride or an oxi-nitride of silicon (Si), titanium (Ti), tantalum (Ta), barium (Ba), zinc (Zn), aluminum (Al) or a combination thereof.

12. The display device of claim 7, wherein the substrate is a glass substrate, a polymer film or a silicon wafer.

13. The display device of claim 7, wherein the inorganic layer is a substrate protective layer, an interlayer insulating layer, an insulation pattern or a combination thereof.

14. The display device of claim 7, wherein the device includes a semiconductor, an electrode, a thin film transistor, an organic light emitting element or a combination thereof.

15. A method for manufacturing a display device, comprising:
providing an inorganic layer on at least one side of a substrate;
irradiating the inorganic layer with a laser; and
providing a device on the inorganic layer irradiated with the laser.

16. The method of claim 15, wherein the laser comprises an excimer laser, a Nd:YAG continuous wave type laser, a Nd:YAG pulse type laser or a carbon dioxide (CO₂) laser.

17. The method of claim 15, wherein the inorganic layer is formed through a chemical vapor deposition (CVD) process, a sputtering process, or a wet coating process.

18. The method of claim 15, wherein the irradiating the inorganic layer with a laser results in the laser-irradiated portion having a layer density at least about 5% higher than a portion not irradiated with the laser.

19. The method of claim 15, wherein the irradiating the inorganic layer with a laser results in the laser-irradiated portion having a hydrogen content of from about 1% to about 90%, compared with a portion not irradiated with the laser.

20. The method of claim 15, wherein the inorganic layer comprises an oxide, a nitride or an oxi-nitride of silicon (Si), titanium (Ti), tantalum (Ta), barium (Ba), zinc (Zn), aluminum (Al), or a combination thereof.
